(19) United States
(12) Patent Application Publication
(10) Pub. No.: US 2006/0278897 A1
(43) Pub. Date: Dec. 14, 2006

(54) Multispectral Energy/Power Meter For Laser Sources

(76) Inventors: Donald F. Heller, Bound Brook, NJ (US); Brian A. Pryor, Ewing, NJ (US); John Curtis Walling, Whitehouse Station, NJ (US)

Correspondence Address: GREENBERG TRAURIG, LLP, MET LIFE BUILDING, 200 PARK AVENUE, NEW YORK, NY, 10166, US

(21) Appl. No.: 11/423,325

(22) Filed: Jun. 9, 2006

Related U.S. Application Data
(60) Provisional application No. 60/689,188, filed on Jun. 10, 2005.

(51) Int. Cl. H01L 29/768

(52) U.S. Cl. 257/222

(57) ABSTRACT

A device for measuring optical power simultaneously for two or more spectral regions. Two or more photodetectors, such as photodiodes, measure the pulse energy and/or power emitted by a laser having output in two or more spectral regions. The laser radiation is transmitted through a diffuser or beamsplitter, then filtered and/or attenuated so that light from each respective spectral region is incident on the active region of a photodiode. The device also includes electronic circuitry with one or more operational amplifiers for each photodiode, integrators and analog-to-digital converters. In a preferred embodiment, the device also includes a microprocessor to provide noise reduction and calibration functions for each photodiode output, and to drive a display or readout.

### CROSS-REFERENCE TO RELATED APPLICATION

This application claims the benefit of U.S. Provisional Application No. 60/689,188, filed Jun. 10, 2005.

### FIELD OF THE INVENTION

The present invention pertains generally to devices for measuring pulse energy and/or power emitted by a laser having output in two or more spectral regions.

### BACKGROUND OF THE INVENTION

Devices for measuring the output of laser sources generally measure the output at single wavelengths or over a relatively narrow spectral region, or provide spectrally integrated measurements of energy or power. A conventional energy/power meter may be provided with some spectral selectivity by placing filters in front of the meter, or by switching between different measuring scales. Conventional meters do not provide measurements of the concurrent spectral composition in energy or power of beams containing multiple wavelengths. Making such measurements generally requires relatively elaborate devices incorporating multiple independent meters or detectors, and optical bench setups which do not lend themselves to incorporation into compact devices. In particular, such arrangements are not suitable for commercial applications (e.g. medical applications).

In order to meet standards of prudent medical treatment with regard to safety and efficacy of light-emitting devices, or in order to meet regulatory requirements, it may be necessary to monitor power and energy simultaneously on multiple wavelengths in a multispectral light beam. Moreover, there is an economic advantage to having a single device for measuring and accurately calibrating the energy, power and/or fluence of laser systems that either simultaneously or sequentially provide light output in a multiplicity of spectral regions. Accordingly, there is a need for a simple, compact, efficient and reliable energy/power meter which can monitor two or more spectral regions either simultaneously or sequentially in time without need of any physical adjustment, and which can conveniently read out energy and/or power measurements in each spectral region.

### SUMMARY OF THE INVENTION

The present invention addresses the above-described need by providing a device for measuring optical power simultaneously or at different times for two or more spectral regions.

A device in accordance with an embodiment of the invention includes two or more photodiodes for measuring the pulse energy and/or power emitted by a laser having output in two or more spectral regions. The laser radiation is transmitted through a diffuser or beamsplitter, then filtered and/or attenuated so that light from each respective spectral region is incident on the active region of a photodiode. The device also includes electronic circuitry with (optionally) one or more operational amplifiers for each photodiode, integrators and analog-to-digital converters. In a preferred embodiment, the device also includes a microprocessor to provide noise reduction and calibration functions for each photodiode output, and to drive a display or readout.

The device may include a multiplicity of detectors such as photodiodes, thermopiles, bolometers, or thermoelectric transducers. Furthermore, the device may include a multiplicity of wavelength separating elements including, for example, dispersing elements such as prisms and gratings, or filters.

In an embodiment, one detector measures all of the energy in the laser output for calibration of the total energy while other detectors measure the energy in specific spectral regions. Such a device is particularly desirable for monitoring the energy in laser beams having several wavelengths, e.g. harmonic generators, stimulated Raman converters or dye lasers. A device constructed according to an embodiment of the invention provides calibrated measurements of energy and/or power in a multiplicity of spectral regions (each of which may be set) without the need for adjustment, and with rarely any need for recalibration.

The foregoing has outlined some features of the present invention so that those skilled in the art may better understand the detailed description of the invention that follows. Additional features of the invention will be described hereinafter that form the subject of the claims of the invention. Those skilled in the art will appreciate that they can readily use the disclosed embodiments as a basis for the designing or modifying other structures for carrying out the same purposes of the present invention and that such other.

### BRIEF DESCRIPTION OF THE DRAWINGS

Other aspects, features and advantages of the present invention will become more fully apparent from the following detailed description, the appended claims, and the accompanying drawings in which similar elements are given similar reference numerals:

FIG. 1 is a block diagram of a device for measuring optical power in two or more spectral regions, according to an embodiment of the invention.

FIG. 2 is a schematic diagram of a light energy measurement device using an integrator and A/D converter in accordance with an embodiment of the invention, applicable to monitoring a laser with fundamental and second harmonic outputs.

### DETAILED DESCRIPTION

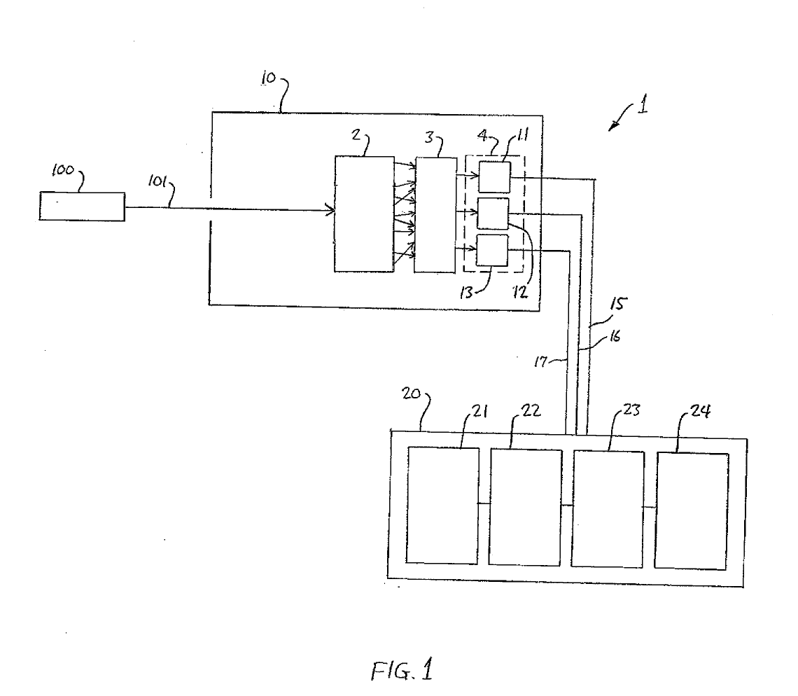

FIG. 1 shows a schematic block diagram of a device 1 constructed according to an embodiment of the invention. A beam of light 101, typically from a laser source 100, enters a light detector portion 10 of the multispectral light meter. A light diffusing or dispersing element 2 (which in practice may include a plurality of elements) increases the spatial extent of the beam without altering its spectral characteristics. The light dispersing element may include a lens, lens array, lenticular lens, Fresnel lens, or a combination thereof. An optical attenuation element may also be placed in the beam to reduce the intensity of light incident on the photosensitive detectors. A set of wavelength separating elements 3 (optical filters, a diffraction grating, prism or the like) divides the beam into components corresponding to different spectral regions of interest.

The spectral components of beam 101 are incident on a set of light detectors 4 including detectors 11, 12, 13 with different sensitivities in respective spectral regions. The detectors are typically photodiodes, but may be any of a variety of detection devices such as bolometers, thermopiles, LEDs, thermoelectric transducers, etc. In particular, detectors for infrared radiation may be semiconductor materials such as PbS, PbSe or AuGe, which may advantageously be cooled using cryogenic liquids or thermoelectric coolers.

Alternatively, light beam 101 may be split by a partial reflector (beamsplitter) into two or more components, with each component incident on one or more detectors having differing spectral responses in the desired spectrally distinct regions. If the partial reflector is replaced by a dichroic beam splitter or prism, or if bandpass or cut-off filters are placed in front of the detectors, spectral selectivity may not be required in the detectors.

Each of detectors 11, 12, 13 sends an electrical signal 15, 16, 17 to the electronic portion 20 of the device. As shown in FIG. 1, the electronic portion may include one or more integrators 21 and digitizers 22, a microprocessor 23 and display device 24. Electronic portion 20 may provide a calibrated digital or analog output proportional to the time-varying amount of light (power or fluence) in each spectral region entering the meter. Alternatively, electronic portion 20 may integrate the time-dependent signals, providing values for the optical energy in each desired spectral region entering the device over a selected period of time. The microprocessor 23 may store calibration constants and serve to subtract out, or ratio out, unwanted noise and signals, and correct for thermal drifts and/or nonlinearities in the optical responses of the detectors.

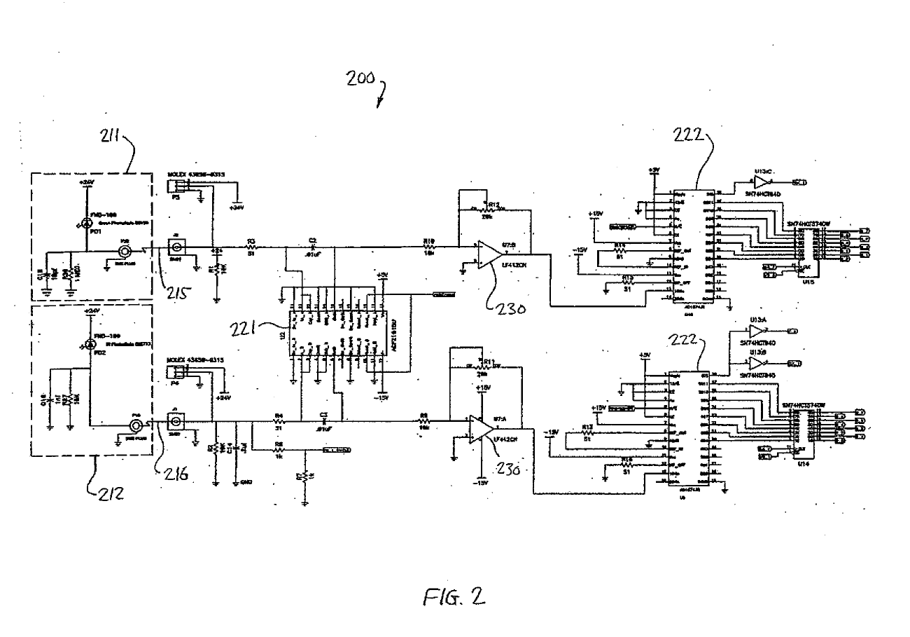

FIG. 2 shows a more detailed schematic diagram of an energy/power meter designed for measuring the energy (or peak power, or average power) in a laser beam having fundamental and second harmonic outputs. A similar device could be used to measure the energy or power in a beam containing any number of harmonics. In an embodiment of the invention, a power meter using detectors 211 and 212 and electronic portion 200 is used to monitor the light output of a Nd:YAG laser with a fundamental output at a wavelength of 1064 nm (infrared) and a second harmonic at a wavelength of 532 nm (green). Light entering the meter passes through a diffusing element as described above, and is incident on the detectors. In this embodiment, two photodiodes are used having semiconductor materials having different bandgaps and thus different sensitivities to the two wavelengths. Alternatively, a beamsplitter and prism arrangement, spectral bandpass filters or cut-off filters may be used to restrict the sensitivities of the two photodiodes to regions around 1064 nm and 532 nm, respectively.

It is often desirable to monitor and display peak power and average power for each spectral region. For continuous-wave (CW) or quasi-continuous laser sources, peak power is measured by the maximum time dependent photocurrent each photodiode produces (calibrated by each photodiode's spectral response at each wavelength, respectively). The average power is obtained by averaging the photocurrent over some time interval and dividing by the length of that interval. For pulsed lasers, the pulse energy is measured by the photocurrent integrated over the laser pulse, and the average power is the photocurrent integrated over some set number of pulses divided by the number of pulses.

This integration can be accomplished by using an RC circuit where the integration time for the photocurrent is according to the RC time constant, or by using a semiconductor integrator chip or other such device. Integration may also be performed by a dedicated analog integration chip (e.g. Burr-Brown ACF2101 Low Noise, Dual Switched Integrator) or by using an analog-to-digital (A/D) converter having sufficient speed to digitize a photovoltage derived from the photocurrent (e.g. by measuring the voltage drop across a resistor through which the photocurrent flows) and using a microprocessor or digital integrator to integrate the digitized signal.

In the embodiment shown in FIG. 2, the output 215 from detector 211 (532 nm) and the output 216 from detector 212 (1064 nm) are connected to a low-noise integrator 221, the outputs of which are amplified using an operational amplifier 230 for each of the two spectral regions. The integrated and amplified signal is then digitized using an A/D converter 222. The digitized signal for each spectral region may then be displayed or processed using techniques known in the art. It will be appreciated that the light detector portion of the meter, the electronic portion and the display may be integrated into a single, compact unit for ease of operation.

In addition to monitoring the energy and power in specific spectral regions, it is often desirable to monitor the total energy or power (e.g. the total energy per pulse in a pulsed laser) in the light beam while simultaneously monitoring a specific wavelength. This may be done by exposing one detector (e.g. detector 11) having broad spectral response to the unfiltered light beam, while simultaneously directing filtered radiation to another detector (e.g. detector 12 and/or 13) responsive in only a narrow spectral region.

It will be appreciated that inputting a digitized photodetector signal to a microprocessor is particularly advantageous because (1) it permits storage of calibration constants, and (2) it permits correction (e.g. by ratio or by subtraction) of signals due to background light, spurious electrical signals, thermal drifts of optical or electronic components, or leakthrough of undesired wavelengths into the spectrally designated photodetector (channel crosstalk).

A particular application of the invention involves calibrating and/or monitoring the output of a Nd:YAG laser at 1064 nm and 532 nm where the laser is used for therapeutic or diagnostic purposes in a medical device. In this case a record must be made of both the total energy and the energy at each wavelength. It will be appreciated that an energy/power meter constructed according to an embodiment of the invention is especially suitable for monitoring the total laser energy and the energy in both wavelengths simultaneously and in real time, with automatic correction and calibration making the meter highly reliable and easy to operate.

It will also be appreciated that a variety of types of lasers may be used with the invention, in addition to Nd:YAG. These include alexandrite lasers with a plurality of output harmonics, and erbium and holmium based laser sources producing output beams at approximately 1.5 μm and 2.0 μm respectively. Furthermore, when more than one laser is employed, measurement of the energy and/or power in the various light beams may or may not be simultaneous.

While there have been shown and described and pointed out the fundamental features of the invention as applied to specific embodiments, it will be understood that various alternatives, substitutions and changes of the form and details of the device described and illustrated and in its operation may be made by those skilled in the art, without departing from the spirit of the invention. Accordingly, the invention is intended to encompass all such alternatives, substitutions and changes which fall within the scope and spirit of the invention and the following claims.

We claim:

1. A device for measuring light energy and/or power in a plurality of spectral regions, the device comprising:
a light diffusing or dispersing element configured to cause a light beam to be incident on a plurality of photosensitive detectors; and
the plurality of photosensitive detectors, having different sensitivities in the respective spectral regions,
wherein the detectors are effective to simultaneously provide an electrical signal corresponding to the energy and/or power in the light beam in each of the respective spectral regions.

2. A device according to claim 1, further comprising an integrator for integrating a signal from at least one of the detectors.

3. A device according to claim 2, wherein the light beam is from a pulsed laser, and the integrator is effective to measure the light energy in a pulse in a given spectral region.

4. A device according to claim 1, further comprising a digitizer for digitizing a signal from at least one of the detectors.

5. A device according to claim 4, further comprising a microprocessor, wherein the digitized signal is input to the microprocessor, and the microprocessor is effective to calculate peak power, average power and/or fluence for each spectral region.

6. A device according to claim 5, wherein the microprocessor has calibration information stored therein, whereby the microprocessor is effective to correct a signal in a given spectral region.

7. A device according to claim 1, wherein one of the detectors is configured to measure at least one of the total energy and total power in the light beam, and another of the detectors is configured to measure at least one of the energy and power in a specific spectral region.

8. A device according to claim 1, further comprising at least one of a bandpass filter, a cut-off optical filter, a prism and a grating, to alter the sensitivity of at least one detector in a given spectral region.

9. A device according to claim 1, wherein the detectors are selected from the group consisting of photodiodes, thermopiles, bolometers, LEDs, thermoelectric transducers, semiconductor infrared detectors and combinations thereof.

10. A device according to claim 1, wherein at least one of the detectors is a semiconductor infrared detector.

11. A device according to claim 10, wherein said semiconductor is one of PbS, PbSe and AuGe.

12. A device according to claim 1, wherein the light beam is from a Nd:YAG laser and the detectors measure light energy and/or power in a first spectral region including 1064 nm and a second spectral region including 532 nm.

13. A device according to claim 12, wherein a first detector is configured to measure the total light energy and/or power in both the first spectral region and the second spectral region, and a second detector is configured to measure the light energy and/or power in one of the first spectral region and the second spectral region.

14. A device according to claim 1, further comprising an optical attenuation element to reduce an intensity of light incident on the photosensitive detectors.

15. A device according to claim 1, further comprising an optical filter for controlling the spectral sensitivity of the photosensitive detectors.

16. A device according to claim 1, wherein the light dispersing element includes at least one of a lens, lens array, lenticular lens and a fresnel lens.

17. A device according to claim 1, wherein the device is incorporated in a medical laser apparatus, and the device is effective to calibrate at least one of laser output energy, power, and fluence.

18. A laser device comprising:
a laser producing an output light beam having energy in one or more spectral regions; and
a device for measuring laser energy and/or power in a plurality of spectral regions, the device including
a light diffusing or dispersing element configured to cause a laser beam to be incident on a plurality of photosensitive detectors, and
the plurality of photosensitive detectors, having different sensitivities in the respective spectral regions,
wherein each of the detectors is configured to produce an electrical signal corresponding to the laser energy and/or power in each of the respective spectral regions.

19. A laser device according to claim 18, the laser comprising a mixed harmonic Nd:YAG laser having light output in a first spectral region including 1064 nm and a second spectral region including 532 nm.

20. A laser device according to claim 18, further comprising a first detector configured to measure a total light energy and/or power in all incident spectral regions.

21. A laser device according to claim 1S, the laser comprising a mixed harmonic Nd:YAG laser having a plurality of output harmonics, and a spectral region of at least one of the detectors corresponds to one of said output harmonics.

22. A laser device according to claim 18, the laser comprising an alexandrite laser having a plurality of output harmonics, and a spectral region of at least one of the detectors corresponds to one of said output harmonics.

23. A laser device according to claim 18, comprising a plurality of lasers of different types producing output light beams in a plurality of spectral regions.

24. A laser device according to claim 23, wherein the lasers include an Nd:YAG laser and an alexandrite laser.

25. A laser device according to claim 23, wherein the lasers include at least one of an erbium based laser source producing an output beam in a spectral region including 1.5 μm and a holmium based laser source producing an output beam in a spectral region including 2.0 μm.

26. A laser device according to claim 23, wherein the output light beams are not simultaneous in time.
